(19) United States
(12) Patent Application Publication
(10) Pub. No.: US 2025/0208613 A1
(43) Pub. Date: Jun. 26, 2025

(54) ERROR ANALYSIS METHOD, ERROR ANALYSIS DEVICE, AND RECORDING MEDIUM

(71) Applicant: Panasonic Intellectual Property Management Co., Ltd., Osaka (JP)

(72) Inventors: Koji OBATA, Tokyo (JP); Sahim YAMAURA, Osaka (JP)

(21) Appl. No.: 18/848,423

(22) PCT Filed: Oct. 26, 2022
(86) PCT No.: PCT/JP2022/039832

§ 371 Date: Sep. 18, 2024

(30) Foreign Application Priority Data
Mar. 31, 2022 (JP) 2022-058096

(51) Int. Cl. G05B 23/02; G01J 5/00; G01J 5/48

(52) U.S. Cl. CPC G05B 23/0221; G01J 5/48; G05B 23/024; G01J 2005/0077

(57) ABSTRACT

An error analysis method according to the present disclosure includes: (S1) obtaining a thermal image taken and an error occurring during an operation of an industrial device; and (S2) training a model by using the thermal image and the error in machine learning to estimate an amount of correction for the industrial device from the thermal image, and determining, using a level of contribution specified by a predetermined method, a portion that affects precision out of the industrial device appearing in the thermal image. The obtaining includes obtaining a temperature of the portion determined in the determining to calculate the amount of correction for the industrial device.

### TECHNICAL FIELD

The present disclosure relates to error analysis methods, error analysis devices, and programs.

### BACKGROUND ART

Redistribution is known in which terminals are repositioned even in an inner chip region by using additional wiring from nearby terminals in the case of packaging using solder bumps, flip-chip bonding, or the like. In recent years, the redistribution has become finer and accordingly, there is a demand for improved mounting precision of mounters. Furthermore, the three-dimensional chip mounting technique has developed and accordingly, there is also a demand for improved chip mounting precision.

Meanwhile, heat generated during the operation of industrial devices such as the mounters cause error issues such as deformation (thermal displacement) of mechanical elements (portions) due to thermal expansion or the like and shifting of machining positions, mounting positions, and the like; thus, the heat is a challenging problem to be solved to improve precision.

To address this problem, a technique has been proposed in which the temperatures of two or more mechanical elements of a machine tool and the temperatures of nearby areas are measured using temperature sensors and an expression for predicting thermal displacement amounts of the mechanical elements and an expression for correcting errors are determined by machine learning (for example, refer to Patent Literature (PTL) 1). According to PTL 1, an accurate correction expression can be derived at a low computational cost.

### CITATION LIST

### Patent Literature

[PTL 1] Japanese Unexamined Patent Application Publication No. 2018-1539028

### SUMMARY OF INVENTION

### Technical Problem

However, even by using the technique proposed in PTL 1, it is not possible to identify which part of an industrial device that generated heat or was deformed by heat significantly contributes to the precision. Therefore, there is a possibility that the temperature of a mechanical element significantly contributing to the precision cannot be measured. Specifically, a correction expression cannot be determined using the temperature of a mechanical element significantly contributing to the precision, and therefore the precision cannot be improved, which is problematic.

The present disclosure has been conceived in view of the above-described circumstances and has an object to provide an error analysis method, an error analysis device, and a program in which a heat-generating area that affects errors can be more accurately identified and the correction precision can be improved.

### Solution to Problem

In order to solve the aforementioned problem, an error analysis method according to one aspect of the present disclosure includes: obtaining a thermal image taken and an error occurring during an operation of an industrial device; and training a model by using the thermal image and the error in machine learning to estimate an amount of correction for the industrial device from the thermal image, and determining, using a level of contribution specified by a predetermined method, a portion that affects precision out of the industrial device appearing in the thermal image. The obtaining includes obtaining a temperature of the portion determined in the determining to calculate the amount of correction for the industrial device.

Note that these general and specific aspects may be implemented using a system, a method, an integrated circuit, a computer program, or a computer-readable recording medium such as a compact disc read-only memory (CD-ROM), or any combination of systems, methods, integrated circuits, computer programs, or recording media.

### Advantageous Effects of Invention

With the error analysis method, etc., according to the present disclosure, a heat-generating area that affects errors can be more accurately identified, and the correction precision can be improved.

### BRIEF DESCRIPTION OF DRAWINGS

FIG. 1 is a block diagram illustrating one example of the configuration of an error analysis device according to an embodiment.

FIG. 2 is a diagram conceptually illustrating a situation in which an image of an operating industrial device according to an embodiment is captured by a thermal camera.

FIG. 3 is a diagram illustrating one example of time-series thermal images according to an embodiment.

FIG. 4 is a block diagram illustrating one example of a detailed configuration of the determiner illustrated in FIG. 1.

FIG. 5 is a diagram conceptually illustrating a model trained in machine learning by a learning processor according to an embodiment.

FIG. 6A is a diagram illustrating a feature value extracted by CNN of the model illustrated in FIG. 5.

FIG. 6B is a diagram for describing the level of contribution specified by the Grad-CAM.

FIG. 6C is a diagram for indicating that a portion that significantly affects errors has been identified.

FIG. 7 is a diagram illustrating one example of the case where portions of an industrial device that affect precision are arranged and displayed in time series on a display according to an embodiment.

FIG. 8 is a flowchart illustrating an error analysis process performed by an error analysis device according to an embodiment.

FIG. 9A is a diagram illustrating one example of a saliency map representing the level of contribution specified using backpropagation.

FIG. 9B is a diagram illustrating one example of a portion identified using the saliency map illustrated in FIG. 9A.

FIG. 10A is a diagram conceptually illustrating a deconvolution network process.

FIG. 10B is a diagram illustrating one example of a reconstructed image representing the level of contribution specified using a deconvolution network.

FIG. 10C is a diagram illustrating one example of a portion identified using the reconstructed image illustrated in FIG. 10B.

FIG. 11 is a diagram illustrating one example of feature importance calculated using, as a feature, ROI extracted from a thermal image.

### DESCRIPTION OF EMBODIMENTS

Each embodiment described below shows one specific example of the present disclosure. The numerical values, shapes, structural elements, steps, the processing order of the steps, etc., shown in the following embodiment are mere examples, and are not intended to limit the present disclosure. Among the structural elements in the following embodiments, structural element not recited in any one of the independent claims will be described as optional structural elements. In every embodiment, various features can be combined.

### Embodiment

Hereinafter, an error analysis method, etc., performed by error analysis device 10 according to an embodiment will be described with reference to the drawings.

### 1 Configuration of Error Analysis Device 10

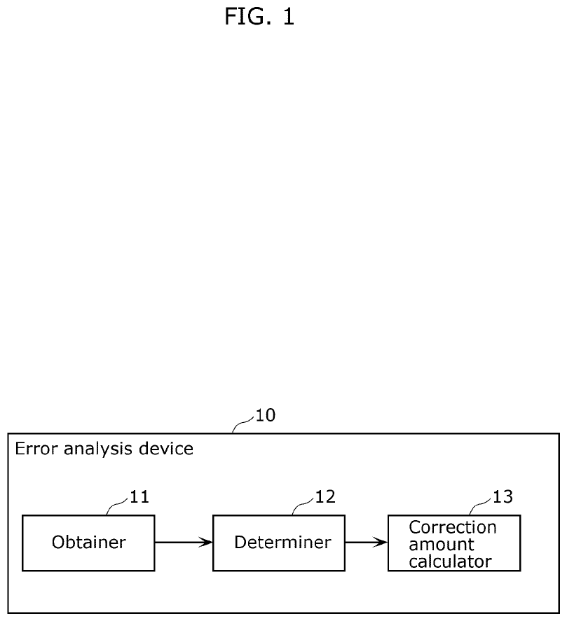

FIG. 1 is a block diagram illustrating one example of the configuration of error analysis device 10 according to the present embodiment.

Error analysis device 10, which is realized by a computer or the like using a model trained in machine learning, includes obtainer 11 and determiner 12 as illustrated in FIG. 1. Error analysis device 10 analyzes a portion of an industrial device that affects errors (precision). Note that in the present embodiment, error analysis device 10 is described as further including correction amount calculator 13, but this is not limiting. Error analysis device 10 is not required to include correction amount calculator 13. Furthermore, in the present embodiment, error analysis device 10 determines, through analysis, a portion that is a heat-generating area of an industrial device that affects errors, and calculates an amount of correction for the industrial device. In the following description, the industrial device may be a mounter and the aforementioned precision may be mounting precision or the industrial device may be a machine tool and the aforementioned precision may be machining precision.

### 1.1 Obtainer 11

Obtainer 11 obtains a thermal image taken and an error occurring during the operation of the industrial device. Obtainer 11 may obtain: thermal images taken in time series during the operation of the industrial device that have been obtained by continuously capturing, in a predetermined period, the thermal image taken during the operation of the industrial device; and errors obtained in said time series.

In other words, the thermal image may be time-series thermal images or may be a single thermal image as long as a portion of the industrial device that affects errors appears in the thermal image.

Note that in the present embodiment, the thermal image taken and the error occurring during the operation of industrial device 50 are described as having been stored, for example, in a storage device or the like located outside error analysis device 10 before obtainer 11 obtains the thermal image and the error.

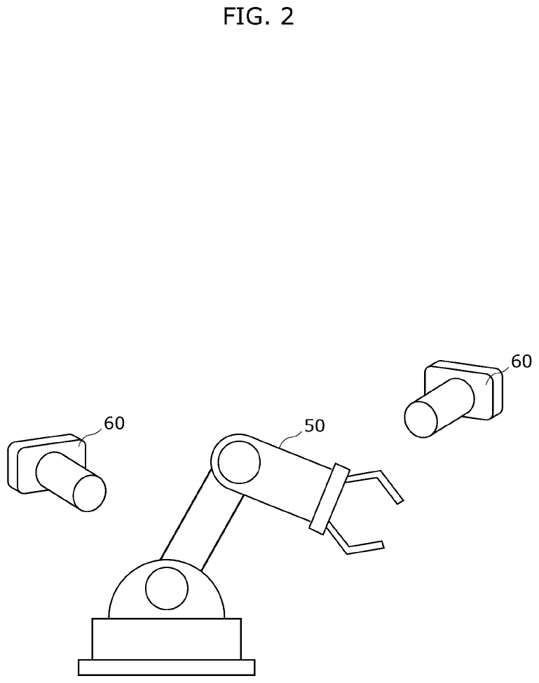

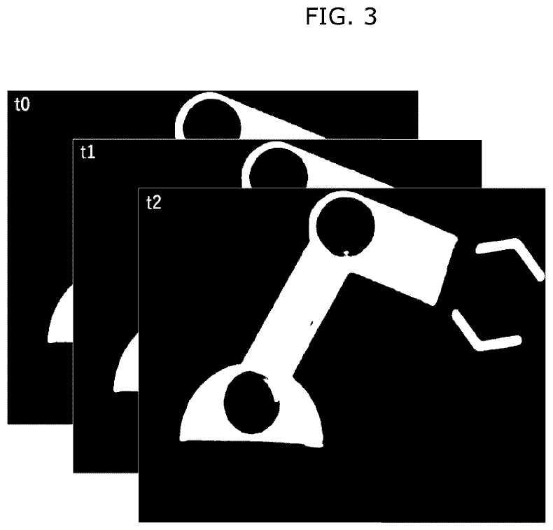

FIG. 2 is a diagram conceptually illustrating a situation in which an image of operating industrial device 50 according to the present embodiment is captured by thermal camera 60. Thermal camera 60 may be a thermographic camera or may be any device that can capture an image of the heat distribution of industrial device 50. FIG. 3 is a diagram illustrating one example of time-series thermal images according to the present embodiment. In FIG. 3, thermal images captured at time t0, time t1, and time t2 are illustrated as one example.

In the present embodiment, for example, as illustrated in FIG. 2, images of operating industrial device 50 are captured using thermal camera 60 in time series in a predetermined period, and thus time-series thermal images such as those illustrated in FIG. 3, for example, are obtained. Furthermore, errors of industrial device 50 are also obtained in said time series after the predetermined period. Subsequently, the time-series thermal images (or the temperature distributions shown by the time-series thermal images) and errors that have been obtained are linked to each other and stored, for example, into a storage device or the like located outside error analysis device 10. Here, the thermal images may be three-dimensional thermal images, but this is not limiting; the thermal images may be two-dimensional thermal images as long as a portion of the industrial device that affects errors appears in the thermal images. Furthermore, the three-dimensional thermal images may be composed of two-dimensional thermal images of industrial device 50 captured from more than one viewpoint.

In this manner, the state of heat generation at target industrial device 50 and final errors are obtained, for example, in time series in the form of three-dimensional data using thermography or the like, and thus the thermal images taken and errors occurring during the operation of industrial device 50 can be stored into the storage device or the like located outside error analysis device 10.

Furthermore, obtainer 11 can obtain a temperature measured by a temperature sensor, as described in more detail hereinafter.

### 1.2 Determiner 12

Determiner 12 analyzes, by artificial intelligence (AI) (a trained model), the relationship between a heat-generating area of industrial device 50 and an error, and determines a portion of industrial device 50 that affects precision. More specifically, first, using the thermal image and the error obtained by obtainer 11, determiner 12 trains a model in machine learning to estimate, from the thermal image, an amount of correction for minimizing errors of industrial device 50. Subsequently, using a level of contribution specified by a predetermined method, determiner 12 determines a portion that affects precision out of industrial device 50 appearing in the thermal image. Here, the model may be a neural network model based on convolution neural networks (CNN) including a convolutional layer or may be a model that uses a decision tree, for example.

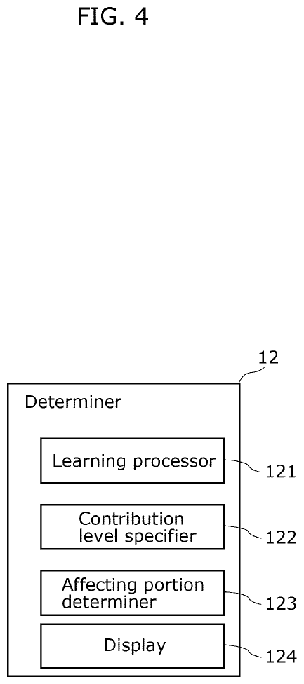

FIG. 4 is a block diagram illustrating one example of a detailed configuration of determiner 12 illustrated in FIG. 1.

In the present embodiment, determiner 12 includes learning processor 121, contribution level specifier 122, affecting portion determiner 123, and display 124, as illustrated in FIG. 4.

Learning processor 121 performs the process of training a model in machine learning. More specifically, using the thermal image and the error obtained by obtainer 11, learning processor 121 trains a model in machine learning to estimate an amount of correction for industrial device 50 from the thermal image.

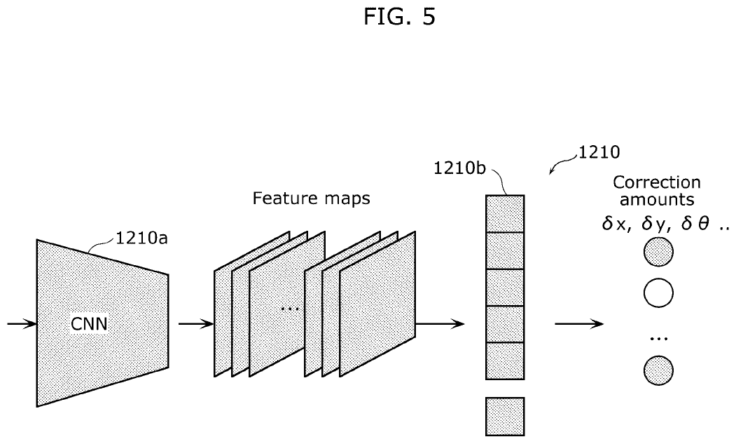

FIG. 5 is a diagram conceptually illustrating model 1210 trained in machine learning by learning processor 121 according to the present embodiment. Model 1210 illustrated in FIG. 5, which is a CNN-based neural network model, includes CNN 1210a and output layer 1210b. When model 1210 is properly trained in machine learning, CNN 1210a can normally obtain spatial and temporal dependence within the thermal images by applying filters such as a kernel. As output layer 1210b, a fully connected layer, a flatten layer, or the like may be used, as appropriate.

In the example illustrated in FIG. 5, using the thermal images and the errors obtained by obtainer 11, learning processor 121 trains, in machine learning, model 1210 to estimate a position correction amount for industrial device 50 from the thermal images. In the example illustrated in FIG. 5, learning processor 121 causes one model 1210 to learn though machine learning to estimate position correction amounts δx, δy, and δθ in the x-direction, the y-direction, and the θ-direction; however, this is not limiting. Models for estimating the x-direction, the y-direction, and the θ-direction may be prepared. In this case, it is sufficient that learning processor 121 cause each of the three models to learn through machine learning. CNN 1210a is trained in machine learning to output an offset map (correction amount map) as a feature map from the thermal images obtained by obtainer 11.

By a predetermined method, contribution level specifier 122 specifies a level of contribution at a position on the thermal images obtained by obtainer 11 to the estimation of the position correction amounts. As the predetermined method for specifying the level of contribution, the gradient-weighted class activation mapping (Grad-CAM) or the like can be used, for example. Note that when model 1210 is a CNN-based model, the predetermined method is not limited to a method that uses the Grad-CAM and may be a method that uses backpropagation or may be a method that uses a deconvolution network. When model 1210 is a model that uses a decision tree, the predetermined method may be a method that uses feature importance. Using the level of contribution specified by the predetermined method, affecting portion determiner 123 determines a portion that affects precision out of industrial device 50 appearing in the thermal images. In other words, using the level of contribution specified by contribution level specifier 122, affecting portion determiner 123 determines a portion that causes an error (displacement). Note that a portion of industrial device 50 may be defined by CAD data, user designation, or the like. In this case, using the level of contribution specified by contribution level specifier 122, affecting portion determiner 123 can determine a portion that is defined by CAD data, user designation, or the like and causes an error (displacement). Affecting portion determiner 123 may determine a portion that causes an error (displacement) using unsupervised segmentation or the like from the level of contribution specified by contribution level specifier 122.

Next, a method, etc., for specifying the level of contribution using the Grad-CAM will be described.

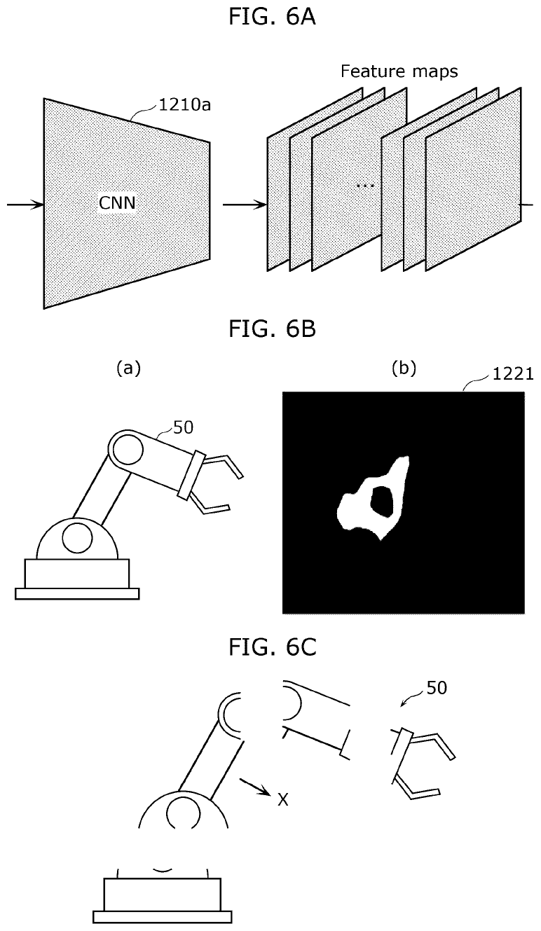

FIG. 6A is a diagram illustrating a feature value (feature map) extracted by CNN 1210a of model 1210 illustrated in FIG. 5. FIG. 6B is a diagram for describing the level of contribution specified by the Grad-CAM. FIG. 6B illustrates, in (b), one example of a heat map representing the level of contribution specified by the Grad-CAM, and conceptually illustrates, in (a), industrial device 50 appearing in a thermal image corresponding to the heat map. FIG. 6C is a diagram illustrating one example of a portion identified using the heat map illustrated in (b) in FIG. 6B.

In the case of using the Grad-CAM, by focusing on the feature value (feature map) extracted by CNN 1210a (the last convolutional layer thereof) as illustrated in FIG. 6A, for example, the level of contribution can be visualized with heat map 1221 such as that illustrated in (b) in FIG. 6B. Subsequently, with reference to heat map 1221 illustrated in (b) in FIG. 6B, a portion of industrial device 50 that is denoted as X in FIG. 6C, for example, can be determined as a portion that significantly affects errors (displacement). More specifically, contribution level specifier 122 can calculate heat map 1221 showing, by using gradient information of the feature value that is output by the convolutional layer (CNN 1210a) of model 1210, a portion that affects precision out of industrial device 50 appearing in the thermal images that have been input to model 1210. In this manner, contribution level specifier 122 can specify the level of contribution at a position on the thermal images obtained by obtainer 11. Using the level of contribution specified by contribution level specifier 122, affecting portion determiner 123 can determine a portion of industrial device 50 that affects precision.

Display 124 displays the portion determined by affecting portion determiner 123. When the portion determined by affecting portion determiner 123 is a portion of industrial device 50 appearing in each of the time-series thermal images, display 124 may arrange and display the determined portions in time series or may display the determined portions one by one in time series. Note that display 124 does not need to be provided on determiner 12 and may be an external display or the like.

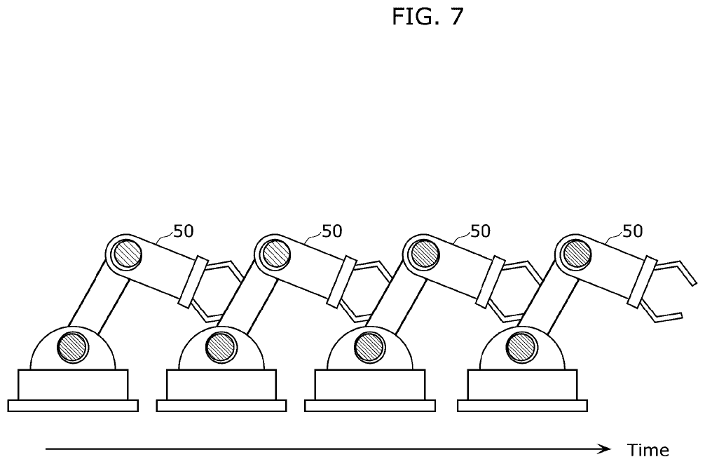

FIG. 7 is a diagram illustrating one example of the case where portions of industrial device 50 that affect precision are arranged and displayed in time series on display 124 according to the present embodiment. In FIG. 7, the circular regions with hatching represent portions that affect precision. Thus, a temporal change in the heat-generating area of industrial device 50 and a change in the heat-generating area of industrial device 50 that affects errors, for example, are visualized, meaning that it is possible to follow changes in the portion that affects precision. Therefore, the temperature sensor can be accurately provided at a position at which the temperature sensor can measure the temperature of a portion of industrial device 50 that affects precision and the temperatures of nearby areas.

In this manner, using AI, determiner 12 can analyze the thermal images obtained by obtainer 11 and clarify which portion generates heat that affects precision.

### 1.3 Correction Amount Calculator 13

Correction amount calculator 13 obtains the temperature of the portion determined by determiner 12, and calculates an amount of correction for industrial device 50.

More specifically, first, the temperature sensor is provided at a position at which the temperature sensor can measure the temperature of the portion determined by determiner 12 and the temperatures of nearby areas. Subsequently, when obtainer 11 obtains the temperature of said portion from the temperature sensor that measures the temperature of said portion, correction amount calculator 13 obtains the temperature of said portion from obtainer 11. Next, using AI such as a model that has been trained in machine learning, correction amount calculator 13 calculates an amount of correction for correcting errors from the obtained temperature of said portion. Note that the AI such as the model that has been trained in machine learning may be a model trained in machine learning by aforementioned learning processor 121 or may be a known model that has been trained.

In this manner, the temperature sensor can be provided in the heat-generating area (portion) of industrial device 50 that has been determined by determiner 12 as affecting precision, to measure temperatures, and thus correction amount calculator 13 can accurately calculate, from the measured temperatures, the amount of correction for correcting errors.

### Operation of Error Analysis Device 10

The following will describe one example of the operation of error analysis device 10 configured as described above.

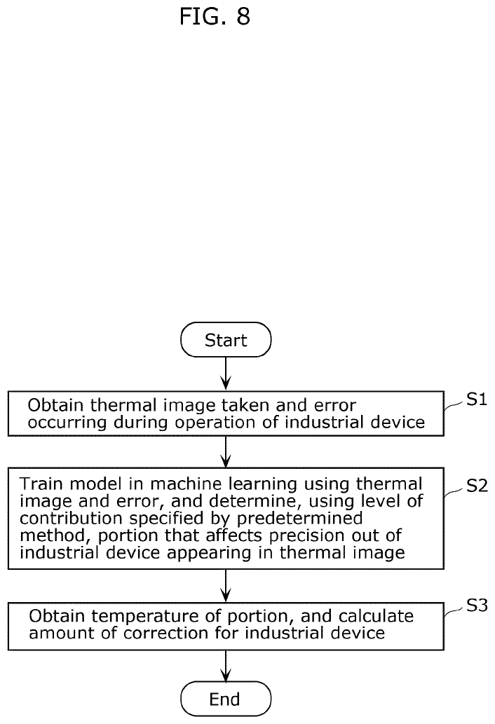

FIG. 8 is a flowchart illustrating an error analysis process performed by error analysis device 10 according to the present embodiment. With reference to FIG. 8, for the sake of simplifying the description, the case of obtaining one thermal image, instead of time-series thermal images, and analyzing an error will be described as an example.

First, error analysis device 10 obtains a thermal image taken and an error occurring during the operation of industrial device 50 (S1).

Next, using the thermal image and the error obtained in Step S1, error analysis device 10 trains a model in machine learning, and determines, using the level of contribution specified by a predetermined method, a portion that affects precision out of industrial device 50 appearing in the thermal image (S2). The model may be a CNN-based neural network model or may be a model that uses a decision tree or the like as described above.

Next, error analysis device 10 obtains the temperature of the portion determined in Step S2, and calculates an amount of correction for industrial device 50 (S3). More specifically, when the temperature sensor is provided so as to measure the temperature of the portion determined in Step S2, error analysis device 10 can obtain the temperature of said portion during the operation of industrial device 50. Thus, using AI or the like, error analysis device 10 accurately calculates an amount of correction for industrial device 50 from the obtained temperature of said portion. Note that the operation in Step S3 does not need to be an essential operation of error analysis device 10. In this case, it is sufficient that error analysis device 10 perform the obtainment step in Step S1 after Step S2. More specifically, it is sufficient that error analysis device 10 obtain the temperature of the portion determined in Step S2 in order to calculate an amount of correction for industrial device 50.

### Advantageous Effects, etc.

As described above, with error analysis device 10 according to the present embodiment, a level of contribution at a position on the obtained thermal images to the estimation of an amount of correction can be specified from a model that has been trained in machine learning, and therefore a portion of industrial device 50 that affects errors (precision) can be determined. Accordingly, the temperature of the portion of industrial device 50 that affects errors (precision) can be measured, and therefore when the temperature of said portion is obtained, an amount of correction for the industrial device can be accurately calculated.

More specifically, an error analysis method according to one embodiment of the present disclosure includes: obtaining a thermal image taken and an error occurring during an operation of industrial device 50; and training a model by using the thermal image and the error in machine learning to estimate an amount of correction for industrial device 50 from the thermal image, and determining, using a level of contribution specified by a predetermined method, a portion that affects precision out of industrial device 50 appearing in the thermal image, and the obtaining includes obtaining a temperature of the portion determined in the determining to calculate the amount of correction for industrial device 50.

Thus, by specifying the level of contribution for the model that has been trained in machine learning, it is possible to more accurately identify a portion that is a heat-generating area of industrial device 50 that affects errors, and it is possible to obtain the temperature of the portion in the heat-generating area that affects errors.

Accordingly, the amount of correction for industrial device 50 can be more accurately calculated. In other words, a heat-generating area that affects errors can be more accurately identified, and the correction precision can be improved.

For example, in the obtaining, thermal images taken in time series during the operation of industrial device 50 that have been obtained by continuously capturing, in a predetermined period, the thermal image taken during the operation of industrial device 50, and errors taken in the time series may be obtained.

This makes it possible to follow a temporal change in the heat-generating area and a change in the heat-generating area that affects errors, for example, meaning that the amount of correction for industrial device 50 can be accurately calculated.

Furthermore, for example, the model may be a convolution neural network (CNN)-based model, and the level of contribution specified by the predetermined method may be a heat map in which the portion that affects the precision out of industrial device 50 appearing in the thermal image is calculated using gradient information of a feature value that is output by a convolutional layer of the model.

Thus, the level of contribution can be specified using the Grad-CAM, and therefore it is possible to accurately identify a portion that is a heat-generating area of industrial device 50 that affects errors.

Furthermore, for example, the model may be a convolution neural network (CNN)-based model, and the level of contribution specified by the predetermined method may be a saliency map calculated based on a gradient magnitude at each pixel of the thermal image by using backpropagation.

Thus, the level of contribution can be specified using the saliency map, and therefore it is possible to more accurately identify a portion that is a heat-generating area of the industrial device that affects errors.

Furthermore, for example, the model may be a convolution neural network (CNN)-based model, and the predetermined method may be a method that uses a deconvolution network in which an intermediate layer of the model is activated to reconstruct the thermal image that is an input image. Thus, the level of contribution can be specified using the method that uses deconvolution, and therefore it is possible to more accurately identify a portion that is a heat-generating area of the industrial device that affects errors.

Furthermore, for example, the model may be a model that uses a decision tree, and the predetermined method may be a method that uses feature importance calculated using impurity of the model.

Thus, the level of contribution can be specified using the feature importance that is used in the decision tree model, and therefore it is possible to more accurately identify a portion that is a heat-generating area of the industrial device that affects errors.

Here, for example, industrial device 50 may be a mounter or industrial device 50 may be a machine tool.

Furthermore, an error analysis device according to one embodiment of the present disclosure includes: obtainer 11 that obtains a thermal image taken and an error occurring during an operation of industrial device 50; and determiner 12 that trains a model by using the thermal image and the error in machine learning to estimate an amount of correction for industrial device 50 from the thermal image, and determines, using a level of contribution specified by a predetermined method, a portion that affects precision out of industrial device 50 appearing in the thermal image, and obtainer 11 obtains a temperature of the portion determined by determiner 12 to calculate the amount of correction for industrial device 50.

With this configuration, by specifying the level of contribution for the model that has been trained in machine learning, it is possible to more accurately identify a portion that is a heat-generating area of the industrial device that affects errors, and it is possible to obtain the temperature of the portion in the heat-generating area that affects errors.

Note that in the present embodiment, the Grad-CAM can be used as the predetermined method for specifying the level of contribution, and therefore the case of using the Grad-CAM has been described thus far as an example, but this is not limiting. The following will describe an example where backpropagation is used as the predetermined method for specifying the level of contribution, an example where deconvolution is used as the predetermined method for specifying the level of contribution, and an example where feature importance is used as the predetermined method for specifying the level of contribution.

First, an example where backpropagation is used as the predetermined method for specifying the level of contribution will be described.

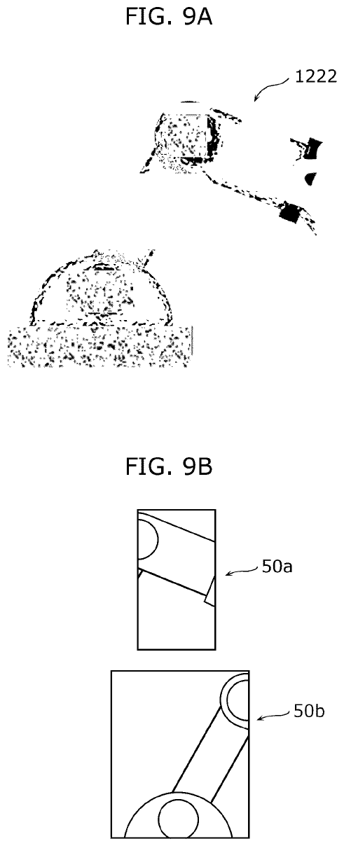

FIG. 9A is a diagram illustrating one example of a saliency map representing the level of contribution specified using backpropagation. FIG. 9B is a diagram illustrating one example of a portion identified using the saliency map illustrated in FIG. 9A. The saliency map is also referred to as an attribution map.

In the case of using backpropagation as the predetermined method for specifying the level of contribution, first, the obtained thermal image is provided as an input image to CNN-based model 1210 illustrated in FIG. 5, for example, to cause CNN-based model 1210 to infer an amount of correction (a forward path is performed), and a feature map extracted by CNN 1210a is obtained. Subsequently, the activation of a CNN layer other than a CNN layer that has output the feature map is set to zero, and backpropagation is performed to calculate a gradient magnitude at each pixel of the input image. Next, on the basis of the calculated gradient magnitude, saliency map 1222 illustrated in FIG. 9A, for example, can be visualized (calculated) as the level of contribution for the input image. From saliency map 1222 illustrated in FIG. 9A, it is possible to determine that portion 50a and portion 50b of industrial device 50 illustrated in FIG. 9B, for example, are portions that significantly affect errors (displacement). More specifically, contribution level specifier 122 applies backpropagation to model 1210 and calculates a gradient magnitude at each pixel of the thermal image that has been input to model 1210. Subsequently, on the basis of the calculated gradient magnitude, contribution level specifier 122 can calculate, as the level of contribution, saliency map 1222 showing a portion that affects precision out of industrial device 50 appearing in the thermal image. In this manner, contribution level specifier 122 can specify the level of contribution at a position on the thermal image obtained by obtainer 11, and using the level of contribution specified by contribution level specifier 122, affecting portion determiner 123 can determine a portion of industrial device 50 that affects precision.

Next, an example where a deconvolution network is used as the predetermined method for specifying the level of contribution will be described.

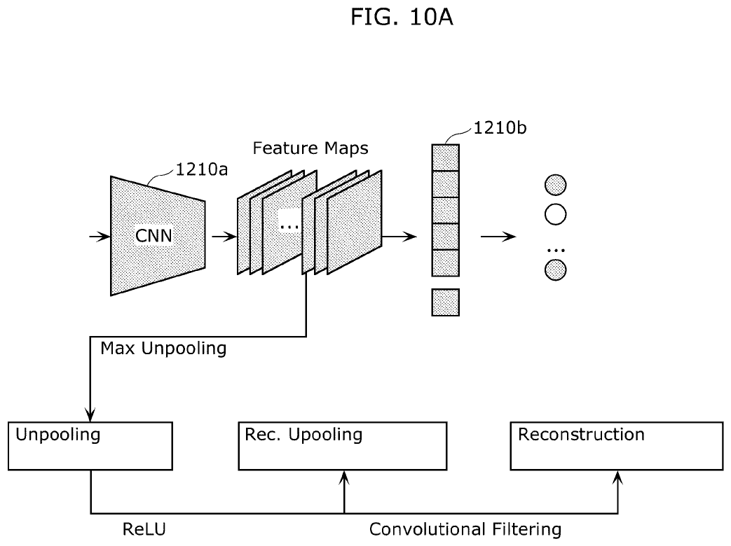

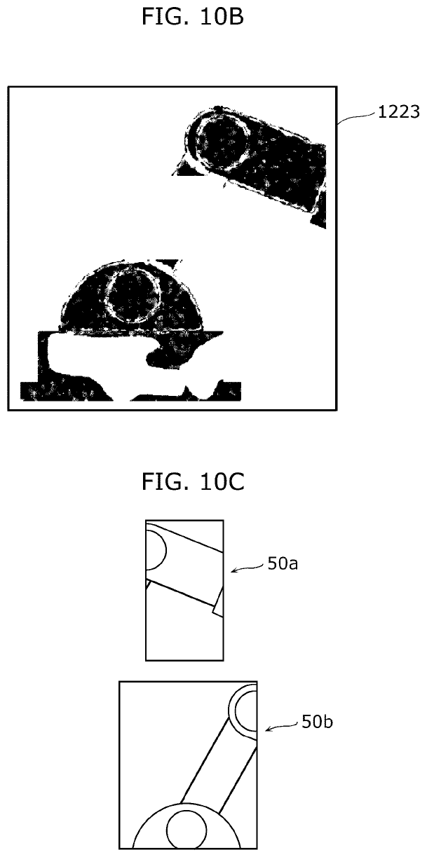

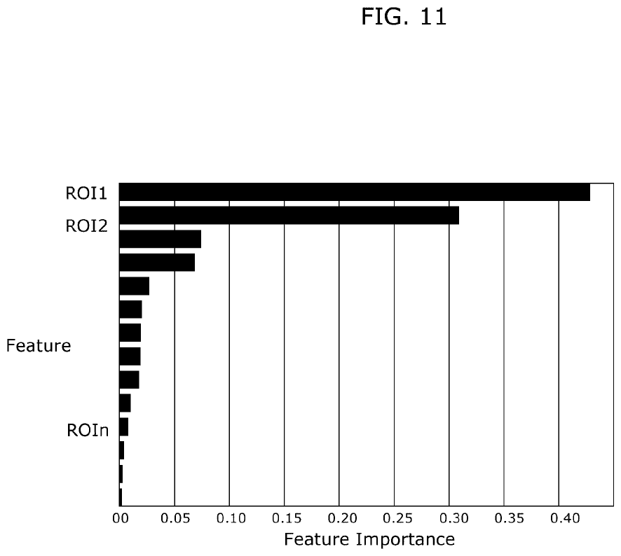

FIG. 10A to FIG. 10C are diagrams for describing the case where a deconvolution network is used as the predetermined method for specifying the level of contribution. FIG. 10A is a diagram conceptually illustrating a deconvolution network process. FIG. 10B is a diagram illustrating one example of a reconstructed image representing the level of contribution specified using a deconvolution network. FIG. 10C is a diagram illustrating one example of a portion identified using the reconstructed image illustrated in FIG. 10B.

In the case where a deconvolution network is used as the predetermined method for specifying the level of contribution, first, a thermal image is provided as an input image to CNN-based model 1210 illustrated in FIG. 5, for example, to cause CNN-based model 1210 to infer an amount of correction, and a feature map extracted by CNN 1210a is obtained. Subsequently, as illustrated in FIG. 10A, a deconvolution network is constructed so as to correspond to each layer of CNN 1210a. Afterwards, the input image is reconstructed by repeating processes such as deconvolution and unpooling on the feature map extracted by CNN 1210a. In other words, in the case of using the deconvolution network, in order to recognize which feature (basically, pixel) of the input image is being searched for by an intermediate layer of model 1210, deconvolution is performed to activate the intermediate layer and reconstruct the input image. Thus, reconstructed image 1223 of the thermal image such as that illustrated in FIG. 10B can be visualized as the level of contribution for the input image. Furthermore, from reconstructed image 1223 illustrated in FIG. 10B, portion 50a and portion 50b of industrial device 50 illustrated in FIG. 10C, for example, can be determined as portions that significantly affect errors (displacement).

More specifically, using a deconvolution network in which an intermediate layer of model 1210 is activated to reconstruct a thermal image that is an input image, contribution level specifier 122 can obtain reconstructed image 1223 showing a portion of industrial device 50 that affects precision. In this manner, contribution level specifier 122 can specify the level of contribution at a position on the thermal image obtained by obtainer 11, and using the level of contribution specified by contribution level specifier 122, affecting portion determiner 123 can determine a portion of industrial device 50 that affects precision.

Next, an example where feature importance is used as the predetermined method for specifying the level of contribution will be described.

As described above, in the case where model 1210 is a model that uses a decision tree, feature importance can be used to specify the level of contribution. Here, the model that uses a decision tree is a model that uses RandomForest, Adaboost, Xgboost, lightGBM, or the like. The model that uses a decision tree is a model made up of multiple nodes in a tree structure. Each of the nodes classifies data by one feature according to a condition. When the model that uses a decision tree is trained in machine learning, data that best meets the condition can be categorized into the same group.

Note that impurity is known as an index of whether each node in a decision tree has created proper condition branches. Furthermore, it is also known that with a decision tree, it is possible to visualize feature importance which is a numerical level of how much an output result is affected for each explanatory variable. Therefore, it is possible to obtain feature importance, which represents the level of contribution, by calculating how much each feature contributes to a reduction in weighted impurity at the time of training the model that uses a decision tree in machine learning.

FIG. 11 is a diagram illustrating one example of feature importance calculated using, as a feature, ROI extracted from a thermal image. The ROI stands for a region of interest. FIG. 11 shows that errors (displacement) are significantly affected in ROI1 and ROI2.

More specifically, using the impurity of the model, contribution level specifier 122 calculates feature importance as the level of contribution. Using the feature importance, which represents the level of contribution, specified by contribution level specifier 122, affecting portion determiner 123 determines, as portions of industrial device 50 that affect precision, portions of industrial device 50 that correspond to ROI1, ROI2, for example.

### Variation 1

In the above embodiment, error analysis device 10 is described as analyzing a portion of industrial device 50 that is a heat-generating area that affects errors, obtaining the temperature of the portion determined by the analysis, and calculating an amount of correction for industrial device 50, but this is not limiting. An error in industrial device 50 is attributed not only to heat during operation, but also oscillation during operation. Therefore, error analysis device 10 may analyze a portion of an industrial device that oscillates and affects errors and may calculate an amount of correction for the industrial device to deal with errors due to oscillation. Thus, it is also possible to deal with reduced precision due to oscillation.

More specifically, an error analysis method according to the present variation may include: obtaining data indicating oscillation observed in time series during an operation of industrial device 50 and an error occurring after the oscillation in the time series; and training a model by using the data and the error in machine learning to estimate an amount of correction for industrial device 50 from the data, and determining, using a level of contribution specified by a predetermined method, a portion that affects precision out of industrial device 50 in the data, and the obtaining may include obtaining data indicating oscillation observed in time series of the portion determined in the determining to calculate the amount of correction for industrial device 50.

Thus, by specifying the level of contribution for the model that has been trained in machine learning, it is possible to more accurately identify a portion of the industrial device that oscillates and affects errors, and therefore it is possible to obtain the oscillation data of the portion that affects errors. Accordingly, the amount of correction for the industrial device can be more accurately calculated. In other words, a portion that oscillates and affects errors can be more accurately identified, and the correction precision can be improved.

Note that in the above-described embodiment, the position correction amount for a portion, such as an arm, of industrial device 50 is cited as an example of the amount of correction, but this is not limiting. The amount of correction may be the frequency of oscillation. In this case, by using a high-speed camera instead of thermal camera 60, it is possible to obtain oscillation data in time series of industrial device 50. Furthermore, in this case, it is sufficient that error analysis device 10 train the model in machine learning to infer the oscillation frequency from the oscillation data.

In this manner, according to the present disclosure, error analysis device 10 can analyze and determine a portion of industrial device 50 that affects errors due to heat or oscillation during operation.

### Other Possible Embodiments

While the error analysis method according to the present disclosure has been described thus far in the embodiment and variations, subjects, devices, and the like in which the processes are performed are not limited to specific ones. The processes may be performed using processors, etc., embedded in specific, locally positioned devices. Alternatively, the processes may be performed using cloud servers, etc., placed at locations different from where local devices are placed.

Furthermore, the amount of correction in the error analysis method, etc., according to the present disclosure is not limited to the oscillation frequency or the position correction amount and may be the remaining useful life (RUL).

Note that the present disclosure is not limited to the above-described embodiment, etc. For example, other embodiments that can be realized by arbitrarily combining or removing structural elements described in the present specification may also be embodiments of the present disclosure. Furthermore, variations obtainable through various changes to the above-described embodiment that can be conceived by a person having ordinary skill in the art without departing from the essence of the present disclosure, that is, the meaning of the recitations in the claims, are also included in the present disclosure.

Furthermore, the present disclosure includes the following cases.
(1) The above-described device is specifically a computer system configured from a microprocessor, a read only memory (ROM), a random access memory (RAM), a hard disk unit, a display unit, a keyboard, and a mouse, for example. A computer program is stored in the RAM or the hard disk unit. Each device achieves its function as a result of the microprocessor operating according to the computer program. Here, the computer program is configured of a combination of command codes indicating instructions to the computer in order to achieve a predetermined function.
(2) Some or all of the structural elements included in the above-described device may be configured from a single system Large Scale Integration (LSI). A system LSI is a super-multifunction LSI manufactured with a plurality of components integrated on a single chip, and is specifically a computer system configured of a microprocessor, a ROM, and a RAM, for example. A computer program is stored in the RAM. The system LSI achieves its function as a result of the microprocessor operating according to the computer program.
(3) Some or all of the structural elements included in the above-described device may each be configured from an IC card that is detachably attached to each device or a stand-alone module. The IC card or the module is a computer system made up of a microprocessor, a ROM, a RAM, and so on. The IC card or the module may include the aforementioned super multifunctional LSI. The IC card and the module achieve their functions as a result of the microprocessor operating according to the computer program. The IC card and the module may be tamperproof.
(4) Moreover, the present disclosure may be the method described above. Furthermore, the present disclosure may be a computer program for implementing these methods using a computer or may be a digital signal of the computer program.
(5) Moreover, the present disclosure may be the aforementioned computer program or digital signal recorded on recording media readable by a computer, such as a flexible disk, a hard disk, a CD-ROM, a magneto-optical disc (MO), a digital versatile disc (DVD), a DVD-ROM, a DVD-RAM, a Blu-ray (registered trademark) disc (BD), or a semiconductor memory, for example. The present disclosure may also be the digital signal recorded on these recoding media.

Furthermore, the present disclosure may be the aforementioned computer program or digital signal transmitted via a telecommunication line, a wireless or wired communication line, a network represented by the Internet, data broadcasting, or the like.

Furthermore, the present disclosure may be a computer system including a microprocessor and a memory. The memory may have the computer program stored therein, and the microprocessor may operate according to the computer program.

Moreover, by transferring the recording medium having the aforementioned program or digital signal recorded thereon or by transferring the aforementioned program or digital signal via the aforementioned network or the like, the present disclosure may be implemented by a different independent computer system.

### INDUSTRIAL APPLICABILITY

The present disclosure can be used for an error analysis method, an error analysis device, and a program, and can be used particularly for error analysis or the like that is performed on errors occurring during the operation of an industrial device such as a mounter or a machine tool.

### REFERENCE SIGNS LIST

10 error analysis device
11 obtainer
12 determiner
13 correction amount calculator
50 industrial device
60 thermal camera
121 learning processor
122 contribution level specifier
123 affecting portion determiner
124 display
1210 model
1210a CNN
1210b output layer
1221 heat map
1222 saliency map

1. An error analysis method comprising:
obtaining a thermal image taken and an error occurring during an operation of an industrial device; and
training a model by using the thermal image and the error in machine learning to estimate an amount of correction for the industrial device from the thermal image, and determining, using a level of contribution specified by a predetermined method, a portion that affects precision out of the industrial device appearing in the thermal image, wherein
the obtaining includes obtaining a temperature of the portion determined in the determining to calculate the amount of correction for the industrial device.

2. The error analysis method according to claim 1, wherein
in the obtaining, thermal images taken in time series during the operation of the industrial device and errors occurring in the time series are obtained, the thermal images being obtained by continuously capturing, in a predetermined period, the thermal image taken during the operation of the industrial device.

3. The error analysis method according to claim 1, wherein
the model is a convolution neural network (CNN)-based model, and
the level of contribution specified by the predetermined method is a heat map in which the portion that affects the precision out of the industrial device appearing in the thermal image is calculated using gradient information of a feature value that is output by a convolutional layer of the model.

4. The error analysis method according to claim 1, wherein
the model is a convolution neural network (CNN)-based model, and
the level of contribution specified by the predetermined method is a saliency map calculated based on a gradient magnitude at each pixel of the thermal image by using backpropagation.

5. The error analysis method according to claim 1, wherein
the model is a convolution neural network (CNN)-based model, and
the predetermined method uses a deconvolution network in which an intermediate layer of the model is activated to reconstruct the thermal image that is an input image.

6. The error analysis method according to claim 1, wherein
the model is a model that uses a decision tree, and
the predetermined method uses feature importance calculated using impurity of the model.

7. The error analysis method according to claim 1, wherein
the industrial device is a mounter, and
the precision is mounting precision.

8. The error analysis method according to claim 1, wherein
the industrial device is a machine tool, and
the precision is machining precision.

9. An error analysis method comprising:
obtaining data indicating oscillation observed in time series during an operation of an industrial device and an error occurring after the oscillation in the time series; and
training a model by using the data and the error in machine learning to estimate an amount of correction for the industrial device from the data, and determining, using a level of contribution specified by a predetermined method, a portion that affects precision out of the industrial device included in the data, wherein
the obtaining includes obtaining data indicating oscillation observed in time series of the portion determined in the determining to calculate the amount of correction for the industrial device.

10. An error analysis device comprising:
an obtainer that obtains a thermal image and an error occurring during an operation of an industrial device; and
a determiner that trains a model by using the thermal image and the error in machine learning to estimate an amount of correction for the industrial device from the thermal image, and determines, using a level of contribution specified by a predetermined method, a portion that affects precision out of the industrial device appearing in the thermal image, wherein
the obtainer obtains a temperature of the portion determined by the determiner to calculate the amount of correction for the industrial device.

11. A non-transitory computer-readable recording medium having recorded thereon a program that causes a computer to perform the error analysis method according to claim 1.
